(19) United States
(12) Patent Application Publication
(10) Pub. No.: US 2005/0185449 A1
(43) Pub. Date: Aug. 25, 2005

(54) Nonvolatile data storage apparatus

(75) Inventors: Shigemasa Shiota, Tachikawa (JP); Kinji Mitani, Higashimurayama (JP); Hiroyuki Goto, Higashimurayama (JP); Hirofumi Shibuya, Matsuda (JP); Fumio Hara, Higashikurume (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/035,227

(22) Filed: Jan. 14, 2005

(30) Foreign Application Priority Data
Feb. 20, 2004 (JP) 2004-044765

(51) Int. Cl. G11C 11/00

(52) U.S. Cl. 365/154

(57) ABSTRACT

The present invention is directed to increase noise immunity and largely improve the reliability of a memory device by controlling input/output buffers in accordance with a noise state of input/output signals. When a user data read-transfer request is received from a host, a controller checks the presence or absence of an error in read CRC data. When there is an error in the CRC data due to the influence of noise and the like, a data transfer control unit outputs a control signal to an I/O buffer switching unit to switch I/O buffers to a Schmitt input. If there is no error in the CRC data, the controller transfers user data to the host. When a re-transfer request is sent from the host after the transfer, the controller determines that the data transferred to the host was influenced by noise or the like and the data transfer control unit performs the control of the I/O buffer switching unit to decrease the drivability of the output buffer, thereby reducing noise.

### CROSS-REFERENCE TO RELATED APPLICATION

The present application claims priority from Japanese patent application No. 2004-044765 filed on Feb. 20, 2004, the content of which is hereby incorporated by reference into this application.

### BACKGROUND OF THE INVENTION

The present invention relates to a technique for improving reliability of a memory device and, more particularly, to a technique effective when applied to noise reduction by controlling an input/output buffer.

As external storing media of a personal computer, a multi function peripheral, and the like, information memory devices such as a CF (Compact Flash) card, a Smart media, a memory stick, and a multimedia card are widely known.

When an information memory device is inserted into a host, there is a case that coupling, a reflection noise, or the like occurs in a data bus, a control signal, or the like. To reduce the noises, for example, the drivability of an I/O buffer is changed by providing different controllers or a damping resistor is attached to a printed wiring board of the information memory device.

An example of a technique of reducing noises by varying the drive level of an output driver is that each of a first output voltage (“H” level) and a second output voltage (“L” level) in a substantially no-load state is controlled to have an absolute value smaller than that of a voltage corresponding to the power source, thereby freely selecting the drivability of a transistor (refer to, for example, Japanese Patent Laid-open No. Hei 6(1994)-326591). In another example, the waveform of a dummy load input signal transmitted via a transmission line provided as a dummy from an output circuit is detected. According to the detection result, an output impedance of the output circuit is controlled, thereby obtaining drivability optimum to the impedance of the transmission line to be driven (refer to, for example, Japanese Patent Laid-open No. Hei 11(1999)-17518).

### SUMMARY OF THE INVENTION

The inventors of the present invention, however, found that the techniques for reducing noises in the information memory devices have the following problems.

There is a tendency that a signal line where noises occur, a noise source, and the like differ according to hosts to which information memory devices are to be inserted. Consequently, an information memory device adapted to each host has to be manufactured, so that the number of kinds of products increases and manufacture management is complicated. It causes a problem that the manufacture cost of the information memory device increases.

In the case of an information memory device to be fixedly inserted to each host, a measure according to a host to which the information memory device is to be inserted can be taken. However, an information memory device such as a CF card is not fixedly inserted to a specific host but is inserted to various hosts. Therefore, a problem arises such that it is difficult to take a specific measure according to a host to which the information memory device is inserted.

An object of the present invention is to provide a memory device having increased noise immunity and largely improved reliability which is realized by controlling input and output buffers in accordance with a noise state of an input/output signal.

The above and other objects and novel features of the invention will become apparent from the description of the specification and the appended drawings.

The outline of representative ones of inventions disclosed in the application will be briefly described as follows.

The present invention provides a memory device comprising: one or more semiconductor memories; and an information processor which reads data stored in an arbitrary semiconductor memory, performs a predetermined process, or gives a data writing operation instruction on the basis of an operation program. The information processor has a buffer switching control unit which switches output voltage and drivability of an output buffer and a signal criterion level of an input buffer provided for at least the information processor among the information processor, the semiconductor memory, and an information processing apparatus which manages the memory device.

The outline of other inventions of the application will be briefly described.

A memory device of the invention has: one or more semiconductor memories; and an information processor which reads data stored in an arbitrary semiconductor memory, performs a predetermined process, and gives a data writing operation instruction or the like on the basis of an operation program. The information processor has a buffer switching control unit which switches output voltage and drivability of an output buffer provided at least in the information processor among the information processor, the semiconductor memory, and an information processing apparatus which manages the memory device in accordance with a control signal. The control signal input to the buffer switching control unit is a signal which is input from the outside of the information processor.

A memory device of the invention has: one or more semiconductor memories; and an information processor which reads data stored in an arbitrary semiconductor memory, performs a predetermined process, or gives a data writing operation instruction or the like on the basis of an operation program. The information processor has a buffer switching control unit which switches a signal criterion level of an input buffer provided at least in the information processor among the information processor, the semiconductor memory, and an information processing apparatus which manages the memory device in accordance with a state of an input/output signal. The buffer switching control unit performs a switching control on the basis of output voltage and drivability of an output buffer provided at least in the information processor among the information processor, the semiconductor memory, and the information processing apparatus on the basis of a control signal which is input from the outside.

Further, a memory device of the invention includes: one or more semiconductor memories; and an information processor which reads data stored in an arbitrary semiconductor memory, performs a predetermined process, or gives a data writing operation instruction or the like on the basis of an operation program. The information processor has a buffer switching control unit which switches output voltage and drivability of an output buffer and a signal criterion level of an input buffer provided at least in the information processor among the information processor, the semiconductor memory, and an information processing apparatus which manages the memory device. The buffer setting information which is read by the buffer switching control unit is stored in the semiconductor memory and is changeable.

A memory device of the invention includes: one or more semiconductor memories; and an information processor which reads data stored in an arbitrary semiconductor memory, performs a predetermined process or gives a data writing operation instruction on the basis of an operation program. The information processor counts the number of the semiconductor memories and, in accordance with the result of counting, switches output voltage and drivability of an output buffer provided at least in the information processor among the information processor, the semiconductor memory, and an information processing apparatus which manages the memory device.

Effects obtained by the representative ones of the inventions disclosed in the application will be described as follows.

(1) Regardless of a noise source, optimum noise immunity performance can be obtained. Thus, reliability of a memory device can be largely improved.

(2) Since a countermeasure against noise for each of an information processor to be assembled becomes unnecessary, the manufacture and management of the memory device is facilitated and the manufacture cost can be reduced.

### BRIEF DESCRIPTION OF THE DRAWINGS

FIG. 1 is a block diagram of an information processing system according to a first embodiment of the invention.

FIG. 2 is an explanatory diagram showing an example of controlling I/O buffers by CRC data in the information processing system of FIG. 1.

FIG. 3 is a flowchart showing an example of transfer of write data in the information processing system of FIG. 2.

FIG. 4 is a flowchart showing an example of transfer of read data in the information processing system of FIG. 2.

FIG. 5 is an explanatory diagram showing an example of controlling I/O buffers by ECC data in the information processing system of FIG. 1.

FIG. 6 is a flowchart showing an example of transfer of write data in the information processing system of FIG. 5.

FIG. 7 is an explanatory diagram showing an example of selection of an I/O buffer in the information processing system of FIG. 5.

FIG. 8 is a flowchart showing an example of transfer of read data in the information processing system of FIG. 2.

FIG. 9 is an explanatory diagram showing an example of monitoring and controlling signals of the I/O buffers by the information processing system of FIG. 1.

FIG. 10 is a circuit diagram showing an example of a noise detecting circuit provided for the information processing system of FIG. 9.

FIG. 11 is a timing chart when the noise detecting circuit of FIG. 9 detects ringing in a falling edge of a signal.

FIG. 12 is a timing chart when the noise detecting circuit of FIG. 9 detects ringing in a rising edge of a signal.

FIG. 13 is a timing chart in the noise detecting circuit in FIG. 9 of the case where no ringing occurs in a trailing edge of a signal.

FIG. 14 is a timing chart when the noise detecting circuit in FIG. 9 detects coupling noise.

FIG. 15 is an explanatory diagram showing an example of an I/O buffer change table when the noise detecting circuit in FIG. 9 detects noise.

FIG. 16 is an explanatory diagram showing an example in which the information processing system of FIG. 1 controls an I/O buffer by a command from a host.

FIG. 17 is a flowchart showing an example of an operation process in a controller provided for the information processing system in FIG. 16.

FIG. 18 is an explanatory diagram showing an example in which the information processing system of FIG. 16 sets an output buffer in accordance with a parameter file.

FIG. 19 is an explanatory diagram showing an example in which the information processing system of FIG. 16 sets an input buffer in accordance with a parameter file.

FIG. 20 is a block diagram of an information processing system according to a second embodiment of the invention.

FIG. 21 is a flowchart showing an operating process of a controller provided for the information processing system of FIG. 20.

FIG. 22 is an explanatory diagram showing an example of selection of an I/O buffer by a power source voltage monitoring unit provided for the information processing system of FIG. 20.

FIG. 23 is an explanatory diagram showing an example in which I/O buffers are controlled by a semiconductor memory in an information processing system according to another embodiment of the invention.

FIG. 24 is a flowchart showing an example of an operating process in a controller provided for the information processing system of FIG. 23.

FIG. 25 is an explanatory diagram showing an example of switching output capability of an output buffer by a memory counting unit provided for the controller in FIG. 23.

FIG. 26 is an explanatory diagram showing an example of controlling I/O buffers in an information processing system according to another embodiment of the invention.

FIG. 27 is an explanatory diagram showing another example of controlling I/O buffers in an information processing system according to another embodiment of the invention.

FIG. 28 is a block diagram showing an example of an information processing system according to a third embodiment of the invention.

FIG. 29 is a block diagram showing another example of the information processing system according to the third embodiment of the invention.

FIG. 30 is an explanatory diagram showing an example of a conversion table of a terminating resistor in the information processing system of FIG. 28.

### DETAILED DESCRIPTION OF THE PREFERRED EMBODIMENTS

Embodiments of the invention will be described in detail hereinbelow with reference to the drawings. In all of the drawings for explaining the embodiments, as a principle, the same reference numeral is given to the same member and its repetitive description will not be given.

### First Embodiment

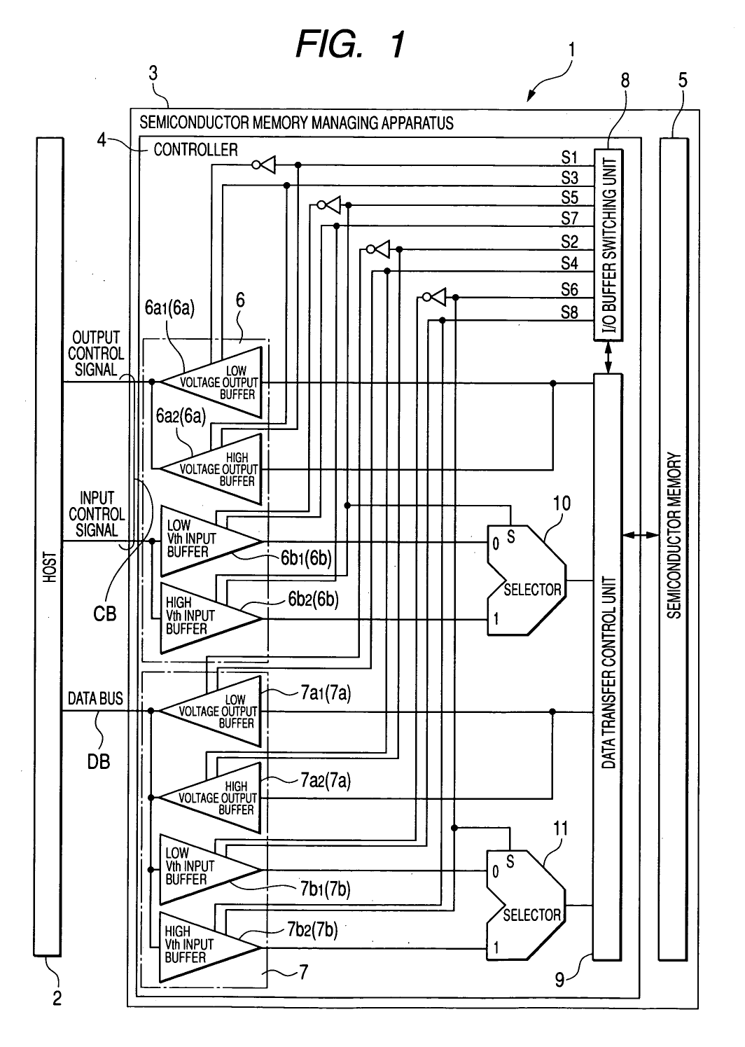

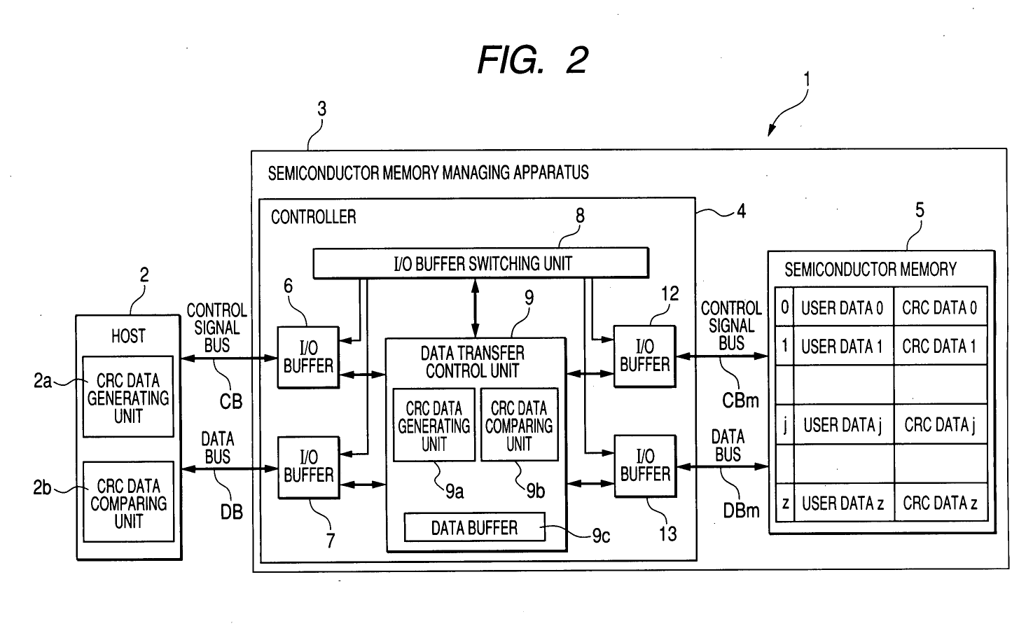

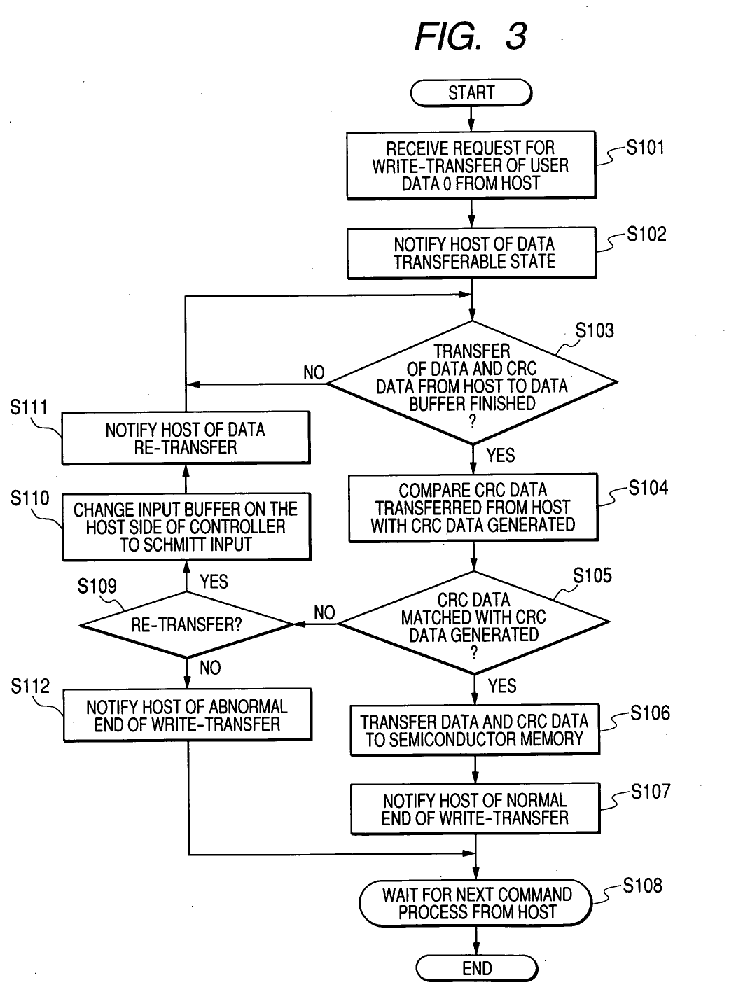

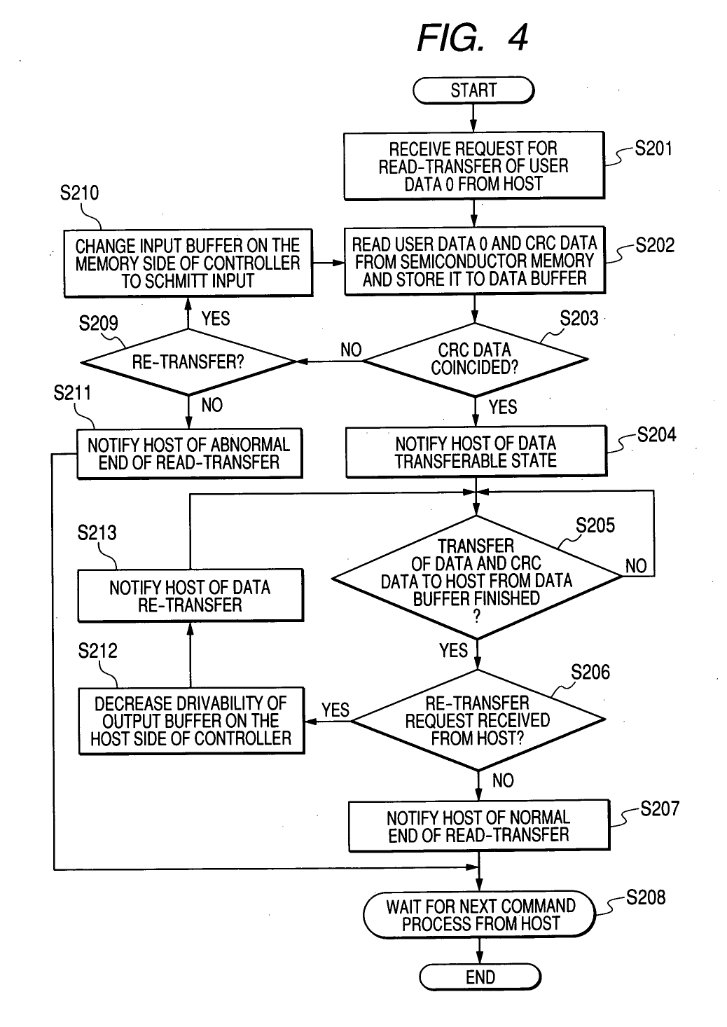

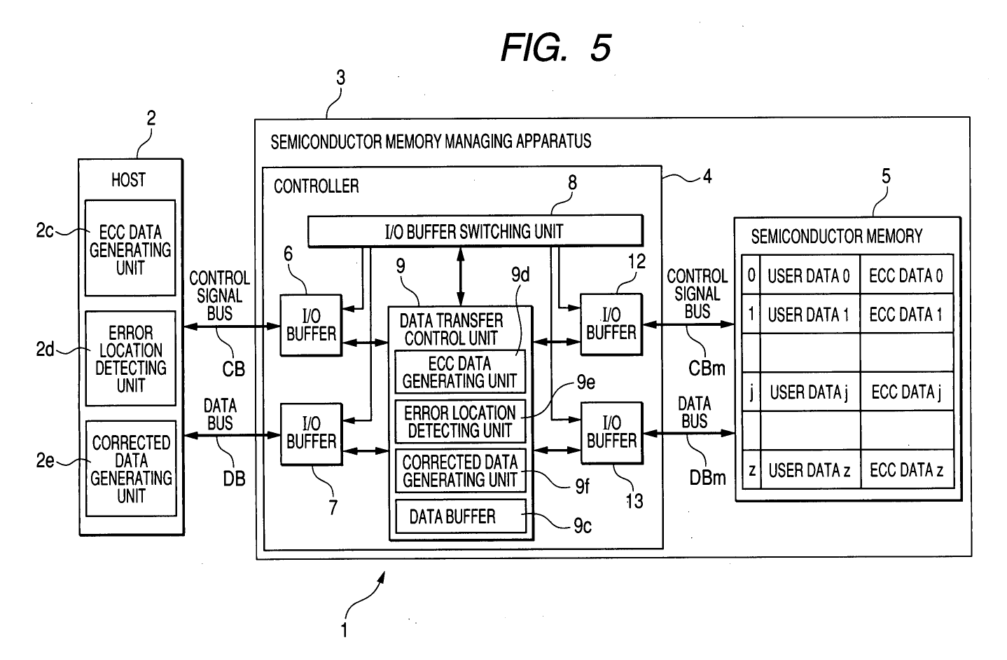

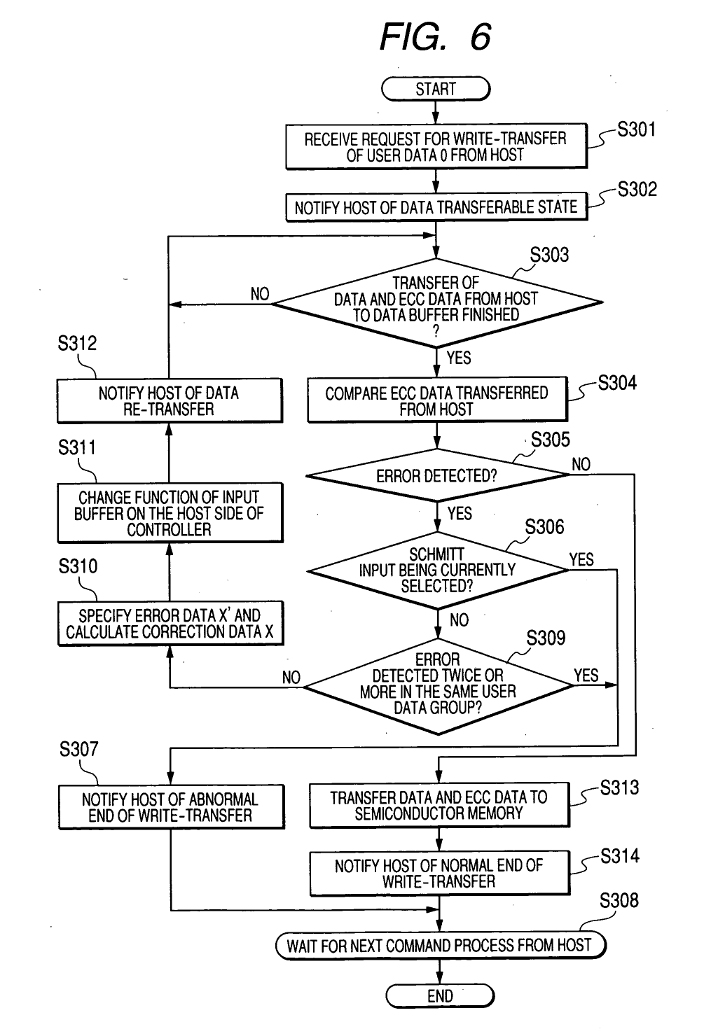

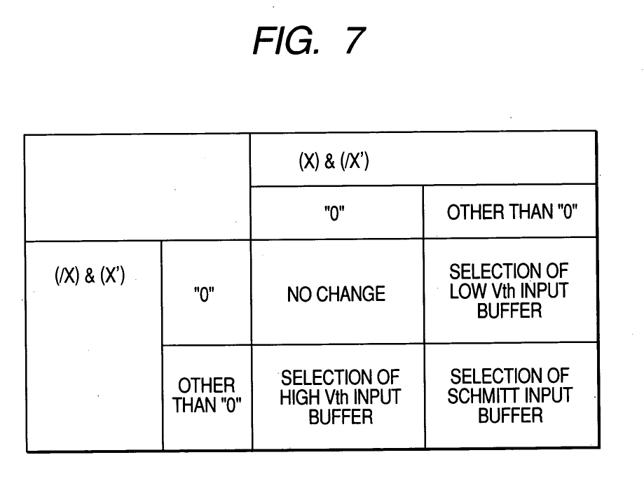

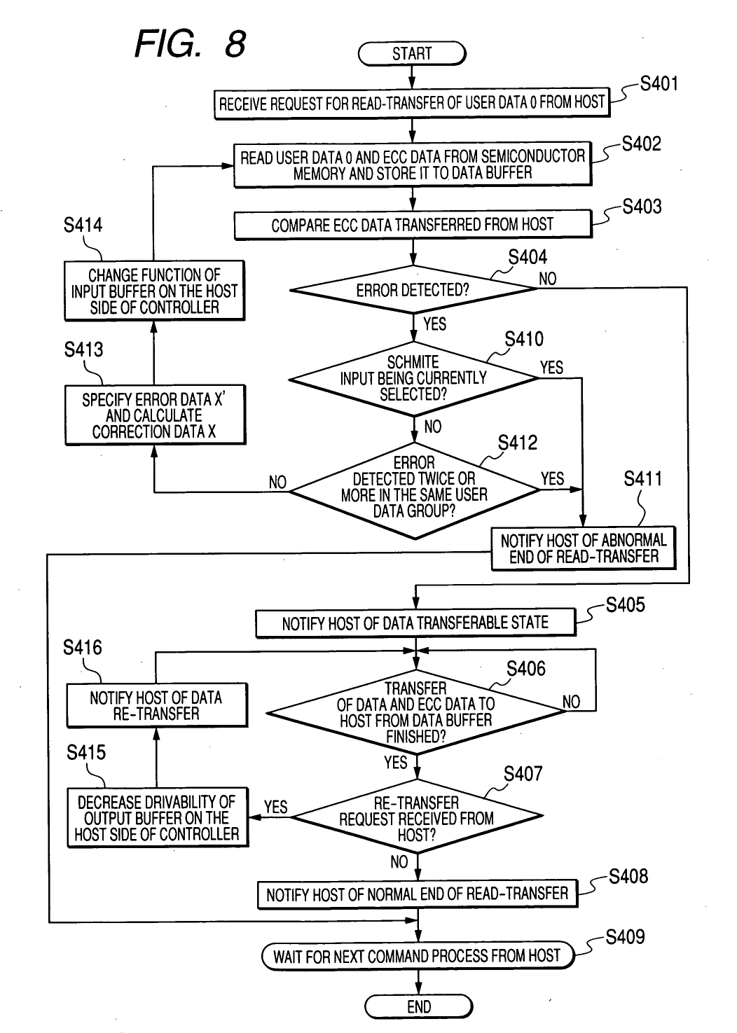

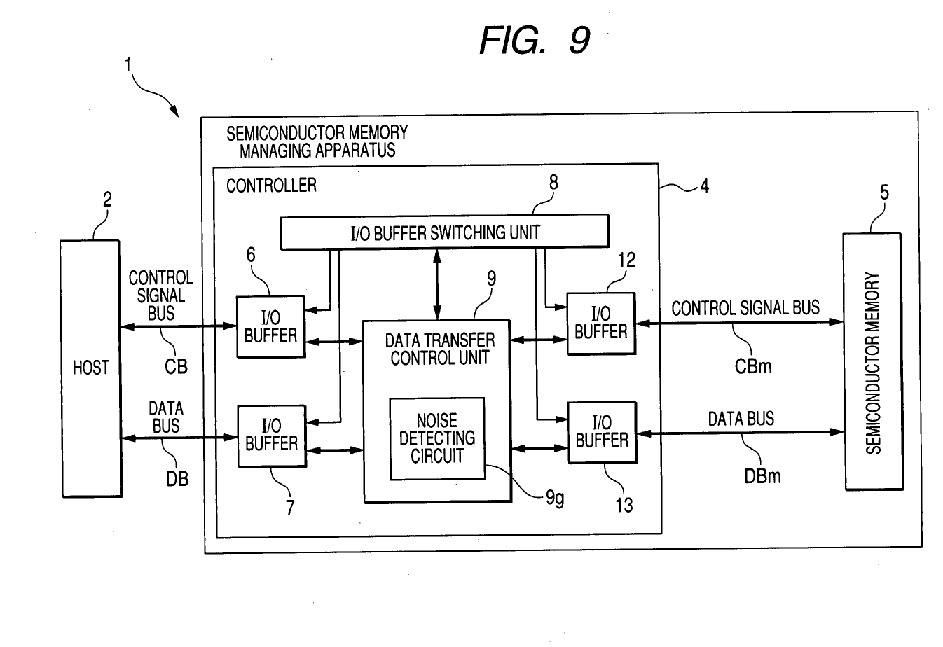

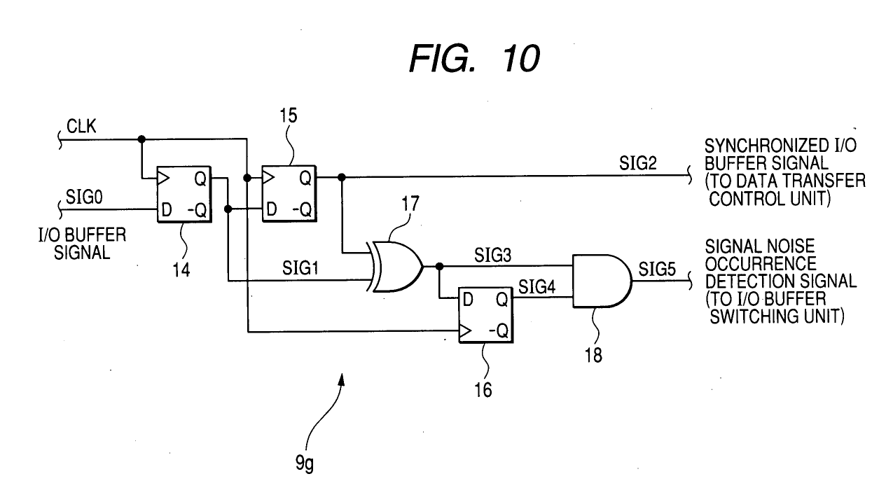

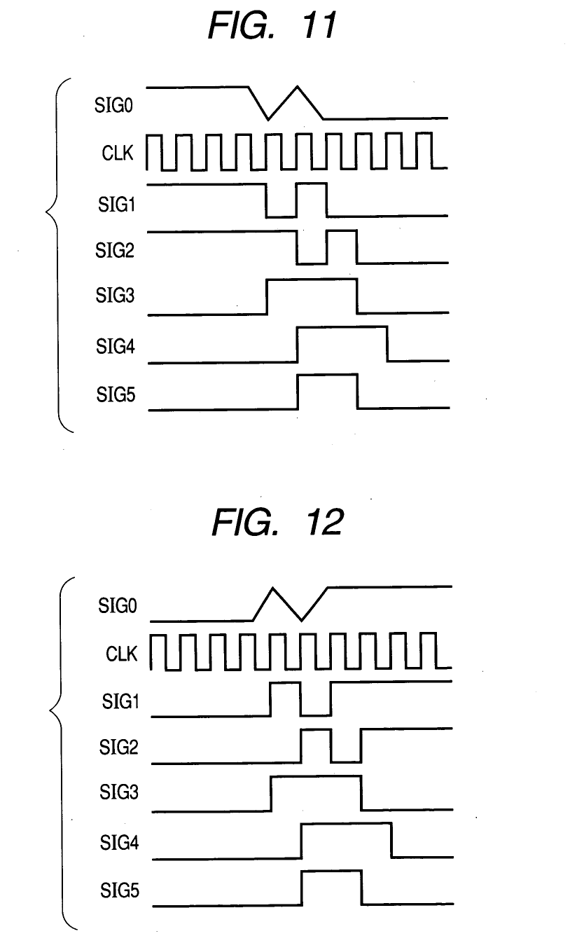

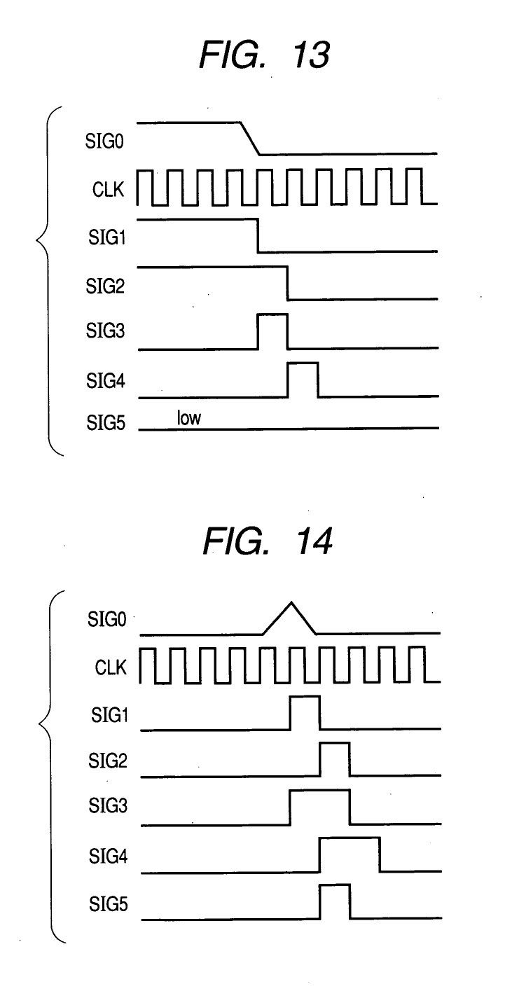

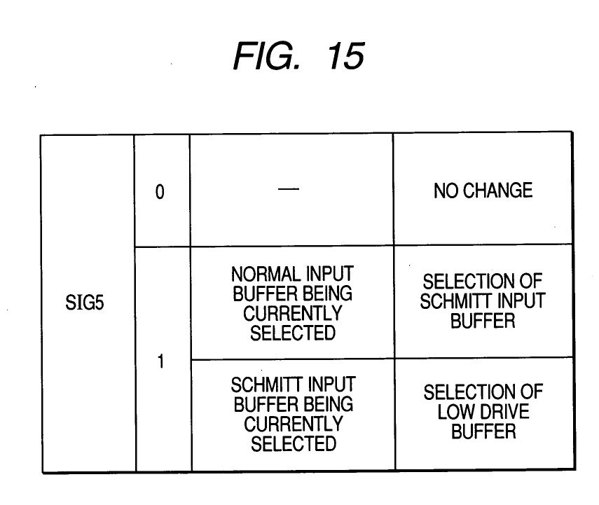

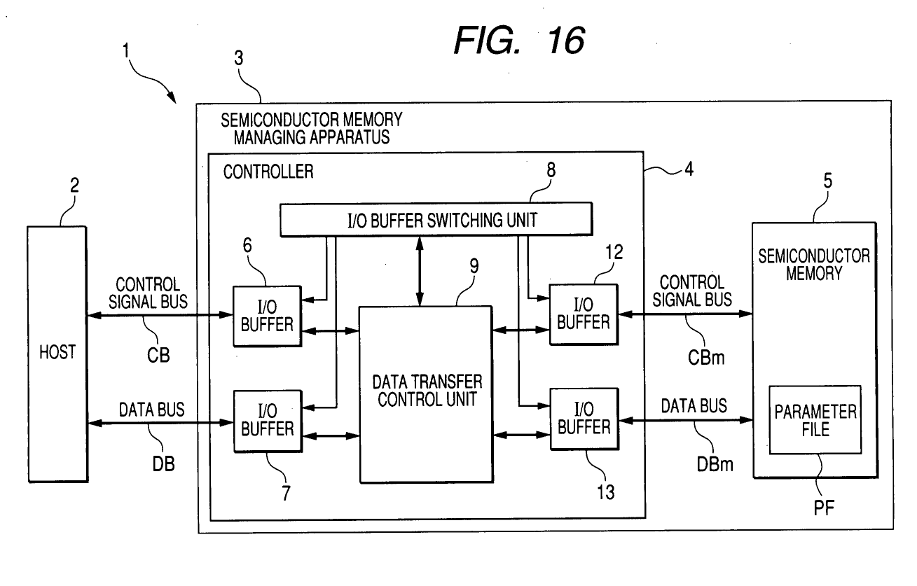

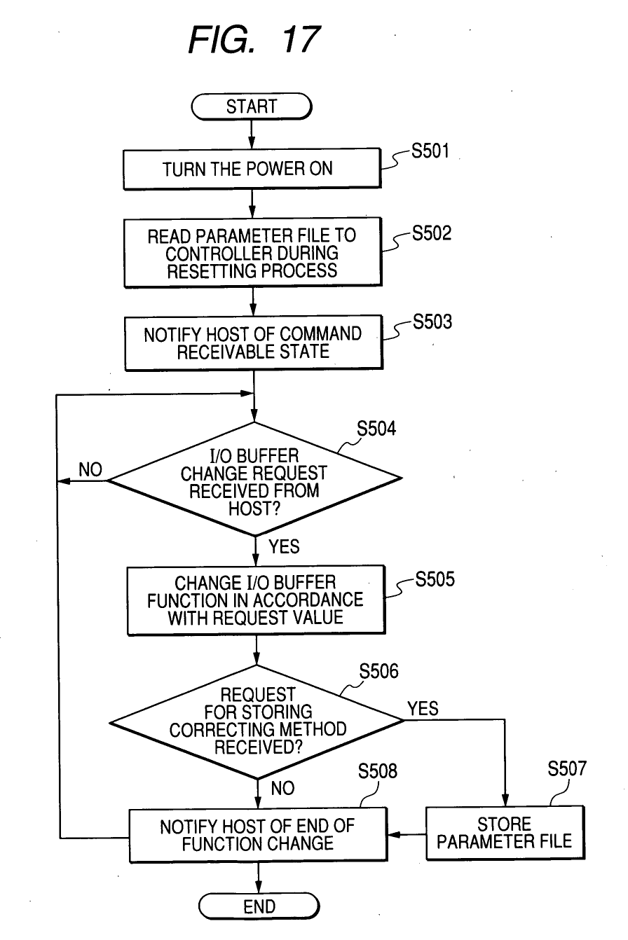

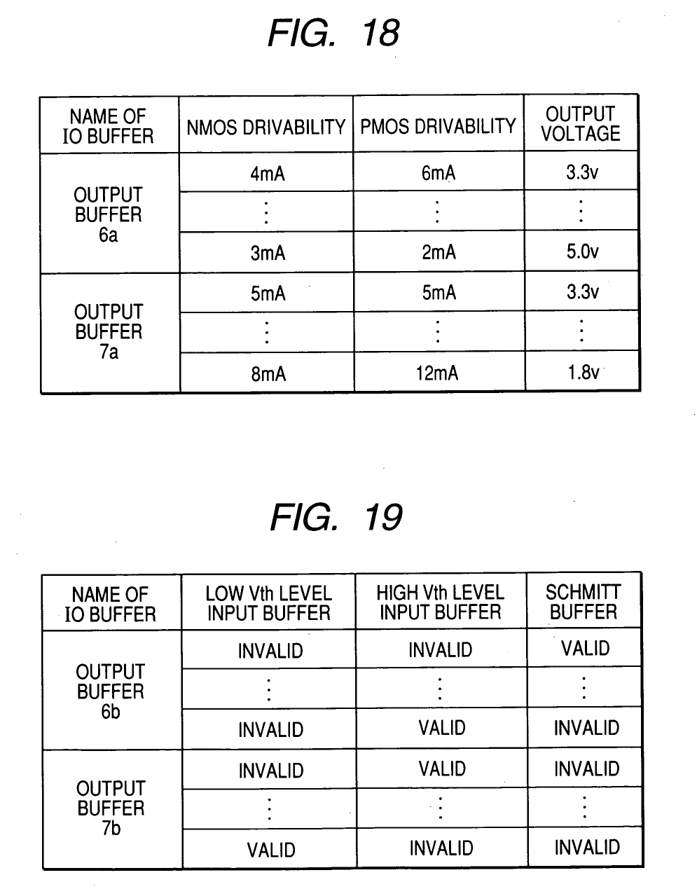

FIG. 1 is a block diagram of an information processing system according to a first embodiment of the invention. FIG. 2 is an explanatory diagram showing an example of controlling I/O buffers by CRC data in the information processing system of FIG. 1. FIG. 3 is a flowchart showing an example of transfer of write data in the information processing system of FIG. 2. FIG. 4 is a flowchart showing an example of transfer of read data in the information processing system of FIG. 2. FIG. 5 is an explanatory diagram showing an example of controlling I/O buffers by ECC data in the information processing system of FIG. 1. FIG. 6 is a flowchart showing an example of transfer of write data in the information processing system of FIG. 5. FIG. 7 is an explanatory diagram showing an example of selection of an I/O buffer in the information processing system of FIG. 5. FIG. 8 is a flowchart showing an example of transfer of read data in the information processing system of FIG. 2. FIG. 9 is an explanatory diagram showing an example of monitoring and controlling signals of the I/O buffers by the information processing system of FIG. 1. FIG. 10 is a circuit diagram showing an example of a noise detecting circuit provided for the information processing system of FIG. 9. FIG. 11 is a timing chart when the noise detecting circuit of FIG. 9 detects ringing in a falling edge of a signal. FIG. 12 is a timing chart when the noise detecting circuit of FIG. 9 detects ringing in a rising edge of a signal. FIG. 13 is a timing chart in the noise detecting circuit in FIG. 9 of the case where no ringing occurs in a trailing edge of a signal. FIG. 14 is a timing chart when the noise detecting circuit in FIG. 9 detects coupling noise. FIG. 15 is an explanatory diagram showing an example of an I/O buffer change table when the noise detecting circuit in FIG. 9 detects noise. FIG. 16 is an explanatory diagram showing an example in which the information processing system of FIG. 1 controls an I/O buffer by a command from a host. FIG. 17 is a flowchart showing an example of an operation process in a controller provided for the information processing system in FIG. 16. FIG. 18 is an explanatory diagram showing an example in which the information processing system of FIG. 16 sets an output buffer in accordance with a parameter file. FIG. 19 is an explanatory diagram showing an example in which the information processing system of FIG. 16 sets an input buffer in accordance with a parameter file.

In the embodiment, an information processing system 1 is constructed by a host (information processing apparatus) 2 and a semiconductor memory managing device (memory device) 3. The host 2 is an information processing apparatus such as a personal computer or a multi-function peripheral.

The semiconductor memory managing device 3 takes the form of a memory card used as an external storage medium of the host 2. The semiconductor memory managing device 3 is constructed by a controller (information processor) 4 and a semiconductor memory 5.

The semiconductor memory 5 is, for example, a flash memory. Although the configuration that one semiconductor memory 5 is provided is employed here, a plurality of semiconductor memories 5 may be provided.

The semiconductor memory 5 is not limited to the flash memory but may be any memory capable of storing data such as an SRAM (Static Random Access Memory), a DRAM (Dynamic RAM), an MRAM (Magnetoresistive RAM), an EPROM (Erasable and Programmable Read Only Memory), or the like. Although the controller and the semiconductor memory are separated from each other in the embodiment, a semiconductor in which the controller, the semiconductor memory, and peripheral parts are integrated may be also used.

The controller 4 includes I/O (Input/Output) buffers 6 and 7, an I/O buffer switching unit (buffer switching control unit) 8, a data transfer control unit (buffer switching control unit) 9, and selectors (buffer switching control units) 10 and 11. The I/O buffers 6 and 7 control transfer of data between the host 2 and the data transfer control unit 9.

The I/O buffer 6 is constructed by an output buffer 6a and an input buffer 6b. The I/O buffer 7 is constructed by an output buffer 7a and an input buffer 7b.

The output buffer 6a is constructed by a low voltage output buffer 6a₁ and a high voltage output buffer 6a₂, and the input buffer 6b is constructed by a low threshold voltage input buffer 6b₁ and a high threshold voltage input buffer 6b₂. The output buffer 7a is constructed by a low voltage output buffer 7a₁ and a high voltage output buffer 7a₂, and the input buffer 7b is constructed by a low threshold voltage input buffer 7b₁ and a high threshold voltage input buffer 7b₂.

Each of the low voltage output buffers 6a₁ and 7a₁ is a buffer having an output of, for example, about 1.8V (or about 3.3V), and each of the high voltage output buffers 6a₂ and 7a₂ is a buffer having an output of, for example, about 5V (or equal to or higher than the output voltage of the low voltage output buffers 6a₁ and 7a₁).

For example, the low threshold voltage input buffers 6b₁ and 7b₁ have an input of a CMOS (Complementary Metal Oxide Semiconductor) level, and the high threshold voltage input buffers 6b₂ and 7b₂ have an input of the TTL (Transistor Transistor Logic) level. They have a Schmitt trigger switching function of canceling noise to a certain degree.

The host 2 and the I/O buffer 6 are connected to each other via a control signal bus CB, and the host 2 and the I/O buffer 7 are connected to each other via a data bus DB. Similarly, I/O buffers 12 and 13 (FIG. 2) and selectors are provided between the semiconductor memory 5 and the data transfer control unit 9. The I/O buffers 12 and 13 and the semiconductor memory 5 are connected to each other via a data bus DBm and a control signal bus CBm as internal buses.

Each of the I/O buffers 12 and 13 is constructed by a low voltage output buffer, a high voltage output buffer, a low threshold voltage input buffer, and a high threshold voltage input buffer in a manner similar to the I/O buffers 6 and 7. Like the selectors 10 and 11, selectors are connected between the semiconductor memory 5 and the low threshold voltage input buffer and the high threshold voltage input buffer.

The data transfer control unit 9 reads a program, data, and the like stored in the semiconductor memory 5 on the basis of an operation program and performs a predetermined process, gives a data write operation instruction, or the like. The data transfer control unit 9 detects error data at the time of data transfer and controls the drivability of the I/O buffers 6, 7, 12, and 13 so that the number of pieces of error data at the time of data transfer becomes the minimum.

The I/O buffer switching unit 8 generates signals for switching the I/O buffers 6, 7, 12, and 13 on the basis of the control of the data transfer control unit 9. From the I/O buffer switching unit 8, output buffer switching signals (control signals) S1 and S2, output capability switching signals (control signals) S3 and S4, input threshold voltage switching signals (control signals) S5 and S6, and Schmitt switching signals (control signals) S7 and S8 are output.

The output buffer switching signal S1 selects, as a buffer to be driven, the low voltage output buffer 6a₁ or high voltage output buffer 6a₂. The output buffer switching signal S2 selects, as a buffer to be driven, the low voltage output buffer 7a₁ or high voltage output buffer 7a₂.

The output capability switching signal S3 switches the drivability of the low voltage output buffer 6a₁ and the high voltage output buffer 6a₂. The output capability switching signal S4 switches the drivability of the low voltage output buffer 7a₁ and the high voltage output buffer 7a₂.

The input threshold voltage switching signal S5 selects, as a buffer to be driven, the low threshold voltage input buffer 6b₁ or high threshold voltage input buffer 6b₂. The input threshold voltage switching signal S6 selects, as a buffer to be driven, the low threshold voltage input buffer 7b₁ or high threshold voltage input buffer 7b₂.

The Schmitt switching signal S7 selects switching of the Schmitt trigger function in the low threshold voltage input buffer 6b₁ and the high threshold voltage input buffer 6b₂. The Schmitt switching signal S8 selects switching of the Schmitt trigger function in the low threshold voltage input buffer 7b₁ and the high threshold voltage input buffer 7b₂.

One of inputs of the selector 10 is connected to the output part of the low threshold voltage input buffer 6b₁ and the other input is connected to the output part of the high threshold voltage input buffer 6b₂. The output part of the selector 10 is connected to the data transfer control unit 9.

One of inputs of the selector 11 is connected to the output part of the low threshold voltage input buffer 7b₁ and the other input is connected to the output part of the high threshold voltage input buffer 7b₂. The output part of the selector 10 is connected to the data transfer control unit 9.

The selector 10 selects and outputs an output signal of the low threshold voltage input buffer 6b₁ or an output signal of the high threshold voltage input buffer 6b₂ on the basis of the input threshold voltage switching signal S5 output from the I/O buffer switching unit 8.

The selector 11 selects and outputs an output signal of the low threshold voltage input buffer 7b₁ or an output signal of the high threshold voltage input buffer 7b₂ on the basis of the input threshold voltage switching signal S6 output from the I/O buffer switching unit 8.

The action of the information processing system 1 in the embodiment will now be described.

First, a process performed in the case of controlling the I/O buffers 6, 7, 12, and 13 on the basis of a result of a CRC (Cyclic Redundancy Check) will be described by using the explanatory diagram of FIG. 2 and the flowcharts of FIGS. 3 and 4.

In this case, in the information processing system 1 (FIG. 1), as shown in FIG. 2, the host 2 is provided with a CRC data generating unit 2a and a CRC data comparing unit 2b. The data transfer control unit 9 has a CRC data generating unit 9a, a CRC data comparing unit 9b, and a data buffer 9c.

The CRC data generating units 2a and 9a generate CRC data. The CRC data comparing units 2b and 9b make comparison to check whether received CRC data and the generated CRC data match each other. In the semiconductor memory 5, CRC data 0 to z is stored together with user data 0 to z.

An error may be detected not only by the CRC but also by a parity check or the like.

A memory data write-transfer process in the controller 4 will now be described with reference to the flowchart of FIG. 3.

When a request for write-transferring user data 0 is received from the host 2 (step S101), the controller 4 notifies the host 2 of a data transferable state (step S102).

Subsequently, the controller 4 determines whether transfer of the user data and CRC data from the host 2 to the data buffer 9c has been finished or not (step S103). When the data transfer has been finished in the process of step S103, the CRC data comparing unit 9b compares the CRC data transferred from the host 2 with the CRC data generated by the CRC data generating unit 9a (step S104) and determines whether the data matches or not (step S105).

When the CRC data matches in the process of step S105, the user data 0 and the CRC data is transferred to the semiconductor memory 5 (step S106). When the host 2 is notified of normal end of the write transfer (step S107), the controller 4 waits for the next command process from the host 2 (step S108).

When the CRC data does not coincide each other due to the influence of noise or the like in the process of step S105, whether the user data is re-transferred or not (for example, whether there is a request for re-transfer from the host 2 or the like) is determined (step S109).

In the case of re-transferring the user data, the controller 4 determines that the CRC data does not match due to the influence of noise, and the data transfer control unit 9 outputs a control signal to the I/O buffer switching unit 8 to switch the input buffers 6b and 7b to the Schmitt input, thereby reducing the influence of noise (step S110).

After that, the controller 4 notifies again the host 2 of the data re-transfer (step S111) and executes the process from the step S103.

When the user data is not re-transferred in the process in step S109, the controller 4 notifies the host 2 of abnormal end (step S112) and waits for the next command process from the host 2 (step S108).

A memory data read-transfer process in the controller 4 will now be described with reference to the flowchart of FIG. 4.

When a request for read-transferring user data 0 is received from the host 2 (step S201), the controller 4 reads the user data 0 and the CRC data 0 stored in the semiconductor memory 5 and stores it to the data buffer 9c (step S202).

The controller 4 checks if the CRC data 0 read from the semiconductor memory 5 coincides with the CRC data generated by the CRC data generating unit 9a (step S203).

If yes, the controller 4 notifies the host 2 of a data transferable state (step S204) and, after completion of the data transfer, notifies the host 2 of end of the data transfer (step S205).

After that, when there is no re-transfer request from the host 2 (step S206), the controller 4 notifies the host 2 of normal end of the read transfer (step S207) and waits for the next command process from the host 2 (step S208).

When the CRC data does not coincide with each other due to the influence of noise or the like in the process of step S203, the host 2 determines whether or not the user data is re-transferred (step S209). In the case of re-transfer, the data transfer control unit 9 outputs a control signal to the I/O buffer switching unit 8 to switch the I/O buffers 12 and 13 to the Schmitt input, thereby reducing noise (step S210). After that, the process from step S202 is executed.

In the case where the user data is not re-transferred in the process of step S209, the controller 4 notifies the host 2 of abnormal end (step S211) and waits for the next command process from the host 2 (step S208).

In the case where there is a re-transfer request from the host 2 in the process of step S206, the controller 4 determines that the data transferred to the host 2 was destroyed by noise or the like. The data transfer control unit 9 controls the I/O buffer switching unit 8 to decrease the drivability of the output buffers 6a and 7a, thereby reducing noise (step S212).

After that, the controller 4 notifies the host 2 of a data re-transfer (step S213) and executes the process from step S205.

FIG. 5 is an explanatory diagram showing an example of the information processing system 1 (FIG. 1) in the case where the I/O buffers 6, 7, 12, and 13 are controlled according to a result of an ECC (Error Correcting Code) check.

As shown in the diagram, the host 2 has an ECC data generating unit 2c, an error location detecting unit 2d, and a corrected data generating unit 2e. The data transfer control unit 9 has an ECC data generating unit 9d, an error location detecting unit 9e, a corrected data generating unit 9f, and a data buffer 9c. In the semiconductor memory 5, user data 0 to z and ECC data 0 to z is stored.

FIG. 6 is a flowchart showing a memory data write-transfer process by the controller 4 in the case of controlling the I/O buffers 6, 7, 12, and 13 in accordance with a result of the ECC check.

When a request for write-transferring the user data 0 is received from the host 2 (step S301), the controller 4 notifies the host 2 of a data transferable state (step S302).

After that, when transfer of the user data and CRC data is finished (step S303), the error location detecting unit 9e calculates the transferred ECC data (step S304) and performs error detection on the ECC data (step S305).

In the case where an error in the ECC data is detected, the data transfer control unit 9 checks whether the input buffers 6b and 7b are currently using the Schmitt input or not (step S306).

In the case where the Schmitt input is being used, the controller 4 notifies the host 2 of abnormal end of the write transfer (step S307) and waits for the next command process from the host 2 (step S308).

In the case where the Schmitt input is not used in the process of step S306, whether or not an error has been detected twice or more in the user data 0 is determined (step S309). If yes, the process of step S307 is executed.

If no, the error location detecting unit 9e specifies error data X′ and the corrected data generating unit 9f calculates corrected data X (step S310). After that, the data transfer control unit 9 selects the input buffer 6b or 7b on the basis of the error data X′ and the corrected data X (step S311).

FIG. 7 is an explanatory diagram showing an example of selection of the input buffer 6b or 7b in the process of step S311.

As illustrated, AND between the error data X′ and inverted corrected data /X as inversion data of the corrected data X and AND between the corrected data X and inverted error data /X′ as inversion data of the error data X′ are calculated. From the result of calculation, a buffer to be selected from the input buffers 6b and 7b is determined.

For example, when the AND between the error data X′ and the inverted corrected data /X is ‘1’ and the AND between the corrected data X and the inverted error data /X′ is other than ‘0’, it is determined that noise occurs on the high level side, and the data transfer control unit 9 selects the high threshold voltage input buffers 6b₂ and 7b₂ in the input buffers 6b and 7b.

In the case where the AND between the error data X′ and the inverted corrected data /X is other than ‘0’ and the AND between the corrected data X and the inverted error data /X′ is ‘0’, it is determined that noise occurs on the low level (reference potential) side, and the data transfer control unit 9 selects the low threshold voltage input buffers 6b₁ and 7b₁.

Further, in the case where both of the AND between the error data X′ and the inverted corrected data /X and the AND between the corrected data X and the inverted error data /X′ are other than ‘0’, it is determined that noise occurs at both the high and low levels, and the data transfer control unit 9 switches the input buffers 6b and 7b to the Schmitt input. After selecting the input buffer 6b or 7b in such a manner, the controller 4 sends a data re-transfer notification to the host 2 (step S312).

When no error is detected in the ECC data in the process of step S305, the controller 4 transfers the user data 0 and the ECC data 0 to the semiconductor memory 5 (step S313).

After completion of the data transfer, the controller 4 notifies the host 2 of normal end of the write-transfer (step S314) and waits for the next command process from the host 2 (step S308).

FIG. 8 is a flowchart showing the memory data read-transfer process by the controller 4 in the case of controlling the I/O buffers 6, 7, 12, and 13 in accordance with the result of the ECC check.

First, when the request for read-transferring the user data 0 is sent from the host 2 (step S401), the controller 4 reads the user data 0 and the ECC data 0 stored in the semiconductor memory 5 and stores it to the data buffer 9c (step S402).

Subsequently, the error location detecting unit 9e calculates the ECC data 0 read from the semiconductor memory 5 (step S403) and detects an error in the ECC data (step S404).

When no error is detected, the controller 4 notifies the host 2 of the data transferable state (step S405). After completion of the data transfer (step S406), the controller 4 determines whether there is a re-transfer request from the host 2 or not (step S407).

When there is no re-transfer request, the controller 4 notifies the host 2 of end of the data transfer (step S408) and waits for the next command process from the host 2 (step S409).

In the case where an error is detected in the process of step S404, the data transfer control unit 9 checks whether the input buffers 6b and 7b are currently using the Schmitt input or not (step S410).

In the case where the Schmitt input is used, it is determined that noise cannot be cancelled. The controller 4 notifies the host 2 of abnormal end of the read transfer (step S411) and performs the process in step S409.

In the case where the Schmitt input is not used in the process of step S410, whether an error has been detected twice or more in the same user data 0 is determined (step S412). If an error has been detected twice or more, the process of step S411 is executed.

If an error has not been detected twice or more, the error location detecting unit 9e specifies the error data X′ and the corrected data generating unit 9f calculates the corrected data X (step S413). After that, the data transfer control unit 9 selects the input buffer 6b or 7b on the basis of the error data X′ and the corrected data X (FIG. 6) (step S414) and executes the process in step S402.

In the case where a re-transfer request is sent from the host 2 in the process of step S407, the controller 4 determines that data transferred to the host 2 was destroyed by noise or the like, and the data transfer control unit 9 controls the I/O buffer switching unit 8 to decrease the drivability of the output buffers 6a and 7a, thereby reducing noise (step S415).

After that, the controller 4 notifies the host 2 of a data re-transfer (step S416) and executes the process from step S406.

FIG. 9 is an explanatory diagram showing an example of the information processing system 1 (FIG. 1) which monitors signals of the I/O buffers 6, 7, 12, and 13 and, in accordance with the result, controls the buffers 6, 7, 12, and 13.

In this case, in the information processing system 1, the data transfer control unit 9 has a noise detecting circuit (noise detector) 9g. As shown in FIG. 10, the noise detecting circuit 9g is constructed by clocked latches 14 to 16, an exclusive OR circuit 17, and an AND circuit 18.

To the clock terminals of the clocked latches 14 to 16, clock signals CLK are input. A signal from the I/O buffer is input to a data terminal D of the clocked latch 14.

To an output terminal Q of the clocked latch 14, a data terminal D of the clocked latch 15 and the other input part of the exclusive OR circuit 17 are connected. To an output terminal Q of the clocked latch 15, one of the input parts of the exclusive OR circuit 17 is connected.

A signal from the data terminal D of the clocked latch 15 is output as a synchronized I/O buffer signal SIG2 to the data transfer control unit 9. The synchronized I/O buffer signal SIG2 is used to determine either noise at the low level or noise at the high level is detected.

To the output part of the exclusive OR circuit 17, the data terminal D of the clocked latch 16 and one of the input parts of the AND circuit 18 are connected. To the output terminal Q of the clocked latch 16, the other input part of the AND circuit 18 is connected. A signal output from the output part of the AND circuit 18 is output as a signal noise occurrence detection signal SIG5 which is output when noise of a signal is detected to the I/O buffer switching unit 8.

A noise detecting operation in the noise detecting circuit 9g will now be described by using the timing charts of FIGS. 11 to 14.

FIGS. 11 to 14 show signal timings of, from top to bottom, a buffer signal SIG0 output from the I/O buffer, the clock signal CLK, a signal SIG1 output from the output terminal Q of the clocked latch 14, the synchronized I/O buffer signal SIG2, a signal SIG3 output from the exclusive OR circuit 17, a signal SIG4 output from the output terminal Q of the clocked latch 16, and the signal noise occurrence detection signal SIG5.

FIG. 11 is a timing chart when the noise detecting circuit 9g detects ringing which occurs at the falling edge of the buffer signal SIG0.

First, in the case where ringing occurs when the buffer signal SIG0 changes from the high level to the low level, the signal SIG1 synchronized with the clock signal CLK is output from the clocked latch 14.

The signal SIG1 is synchronized again with the clock signal CLK by the clocked latch 15 to generate the synchronized I/O buffer signal SIG2. By the operation, a sync signal which is delayed from the ringing by one clock is generated.

The exclusive OR circuit 17 obtains exclusive OR between the signal SIG1 and the synchronized I/O buffer signal SIG2, outputs the signal SIG3, and detects a signal change. After that, the clocked latch 16 makes the signal SIG3 synchronized with the clock signal CLK, thereby generating the signal SIG4 as a sync signal delayed from the signal SIG3 by one clock.

By obtaining the AND between the signals SIG3 and SIG4 by the AND circuit 18, the signal noise occurrence detection signal SIG5 output from the AND circuit 18 changes from the low level to the high level so that occurrence of noise is detected.

FIG. 12 is a timing chart showing the case where the noise detecting circuit 9g detects ringing which occurs at the rising edge of the buffer signal SIG0.

First, in the case where ringing occurs when the buffer signal SIG0 changes from the low level to the high level, the signal SIG1 synchronized with the clock signal CLK is output from the clocked latch 14.

After that, the signal SIG1 is output as the synchronized I/O buffer signal SIG2 as a sync signal delayed by one clock by the clocked latch 15.

The exclusive OR circuit 17 obtains exclusive OR between the signal SIG1 and the synchronized I/O buffer signal SIG2, outputs the signal SIG3, and detects a signal change.

The clocked latch 16 makes the signal SIG3 synchronized with the clock signal CLK, thereby generating the signal SIG4 as a sync signal delayed from the signal SIG3 by one clock. By obtaining the AND between the signals SIG3 and SIG4 by the AND circuit 18, the signal noise occurrence detection signal SIG5 output from the AND circuit 18 changes from the low level to the high level so that occurrence of noise is detected.

FIG. 13 is a flowchart of the case where noise such as ringing does not occur when the buffer signal SIG0 changes from the high level to the low level.

When the buffer signal SIG0 changes from the high level to the low level, synchronously, the signal SIG1 is output from the clocked latch 14.

The signal SIG1 is delayed by one clock by the clocked latch 15, thereby generating the synchronized I/O buffer signal SIG2. The exclusive OR circuit 17 obtains exclusive OR between the signal SIG1 and the synchronized I/O buffer signal SIG2 and outputs the signal SIG3.

The clocked latch 16 makes the signal SIG3 synchronized with the clock signal CLK, thereby generating the signal SIG4 as a sync signal delayed from the signal SIG3 by one clock. The AND circuit 18 obtains the AND between the signals SIG3 and SIG4.

Since there is no period in which the signals SIG3 and SIG4 are at the high level at the same time, the signal noise occurrence detection signal SIG5 which remains at the low level is output from the AND circuit 18. Therefore, noise in the buffer signal SIG0 is not detected.

FIG. 14 is a timing chart showing the case where the noise detecting circuit 9g detects coupling noise in the buffer signal SIG0.

When coupling noise occurs in the low-level buffer signal SIG0, the signal SIG1 is output from the clocked latch 14 synchronously with the clock signal CLK. After that, the signal SIG1 is delayed by one clock by the clocked latch 15, thereby generating the synchronized I/O buffer signal SIG2. The exclusive OR circuit 17 obtains the exclusive OR between the signal SIG1 and the synchronized I/O buffer signal SIG2, outputs the signal SIG3, and detects a signal change.

The clocked latch 16 makes the signal SIG3 synchronized with the clock signal CLK, thereby generating the signal SIG4. The AND circuit 18 obtains the AND between the signals SIG3 and SIG4, thereby detecting that the signal noise occurrence detection signal SIG5 output from the AND circuit 18 changes from the low level to the high level and noise occurs.

FIG. 15 is an explanatory diagram showing an example of a change table of the I/O buffers 6, 7, 12 and 13 switched by the data transfer control unit 9.

The data transfer control unit 9 changes the I/O buffers 6, 7, 12, and 13 on the basis of the signal noise occurrence detection signal SIG5. For example, when the signal noise occurrence detection signal SIG5 is ‘0’ (low level), no noise occurs, so that the I/O buffers 6, 7, 12 and 13 are unchanged.

When the signal noise occurrence detection signal SIG5 is ‘1’ (high level), it is determined that noise occurs. When the normal input is being currently chosen in the I/O buffers 6, 7, 12, and 13, the input buffers 6b and 7b are selected to use the Schmitt input. In the case where noise occurs even after the Schmitt input is selected, a control for switching the output buffers 6a and 6b to the low voltage output buffers 6a₁ and 7a₁ is executed.

If the Schmitt input is used in the input buffers 6b and 7b when the signal noise occurrence detection signal SIG5 is ‘1’, a switching control is performed so as to use the low threshold voltage input buffers 6b₁ and 7b₁.

FIG. 16 is an explanatory diagram showing an example of the information processing system 1 which controls the I/O buffers 6, 7, 12, and 13 by a command from the host 2.

In this case, in the information processing system 1 (FIG. 1), a parameter file (buffer setting information) PF for setting the I/O buffers 6, 7, 12, and 13 is stored together with user data in the semiconductor memory 5.

The operating process in the controller 4 in FIG. 16 will be described by using the flowchart of FIG. 17.

When the power source is turned on (step S501), the controller 4 reads the parameter file PF during a resetting process (step S502). Alternately, without reading the parameter file PF, the controller 4 may generate default data in place of the parameter file PF during the resetting process.

After completion of reading of the parameter file PF, the host 2 is notified of a command acceptable state (step S503). When a command requesting an I/O buffer change is received from the host 2 (step S504), the controller 4 changes the I/O buffer function in accordance with the change request command (step S505).

FIG. 18 is an explanatory diagram showing an example of setting of the output buffers 6a and 7a in accordance with the parameter file PF. FIG. 19 illustrates an example of setting the input buffers 6b and 7b in accordance with the parameter file PF.

As shown in the diagrams, according to the parameter file PF, the drivability of NMOS-side transistors, drivability of PMOS-side transistors, and output voltages in the output buffers 6a and 7b can be changed.

In the input buffers 6b and 7b, switching of the low threshold voltage input buffers 6b₁ and 7b₁, the high threshold voltage input buffers 6b₂ and 7b₂, and the Schmitt input can be set according to the parameter file PF.

After that, whether a request for storing the change in the I/O buffer function is received from the host 2 or not is determined (step S506). If yes, the parameter file PF is stored in the semiconductor memory 5 (step S507).

When there is the storing request in the process of step S506 or after the process in step S507, the controller 4 notifies the host 2 of end of the buffer function change (step S508) and returns to the process of step S504.

In such a manner, according to the first embodiment, the noise state is detected and the characteristics of the I/O buffers 6, 7, 12, and 13 can be controlled so as to be adapted to the noise characteristic. Thus, the semiconductor memory managing device 3 having an excellent noise immunity characteristic can be realized.

Since the noise immunity can be largely improved regardless of the host 2 to which the semiconductor memory managing device 3 is inserted, it is unnecessary to form a semiconductor memory managing device having a specification for preventing noise in accordance with the host 2. Thus, the manufacture and management costs and the like can be largely reduced.

### Second Embodiment

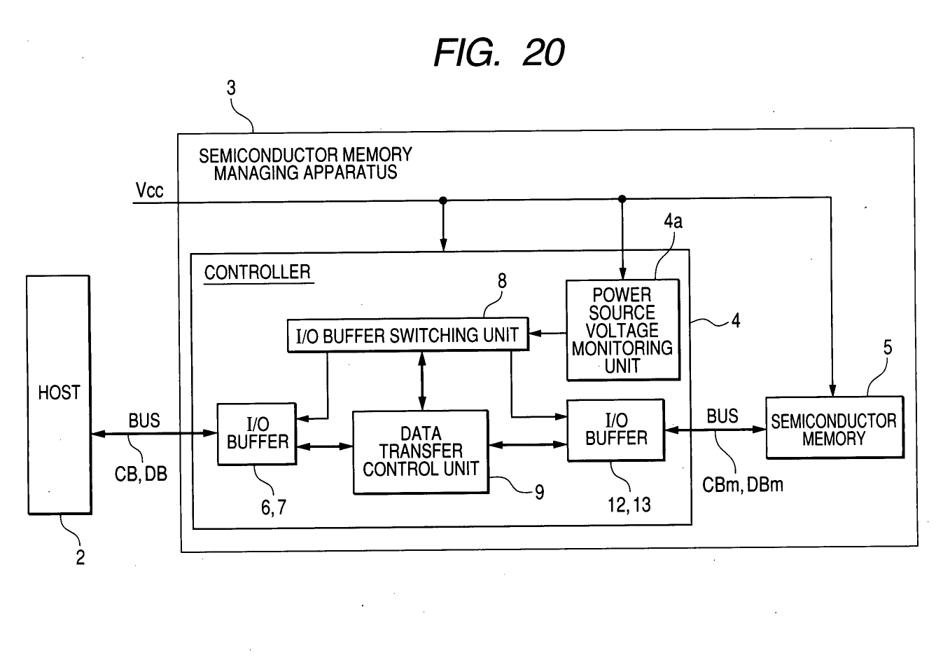

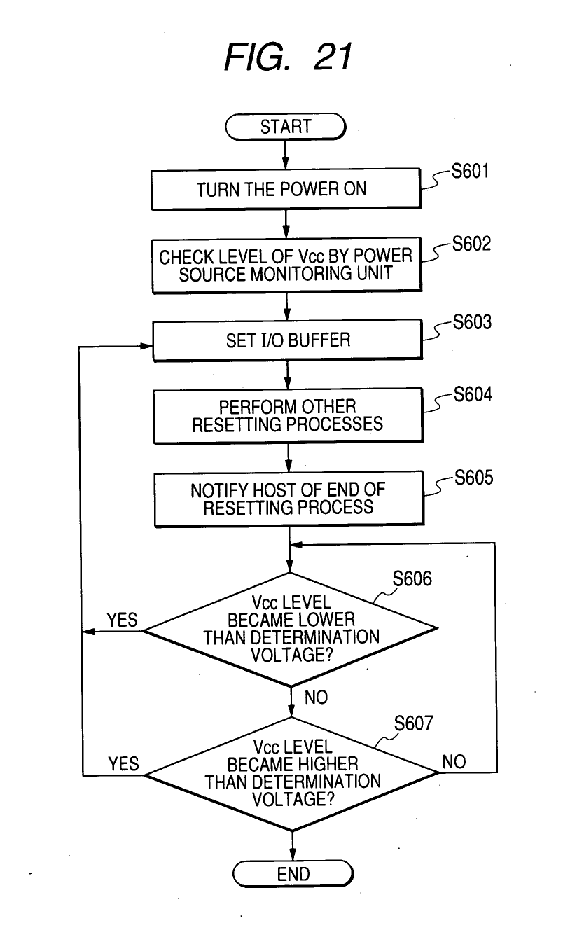

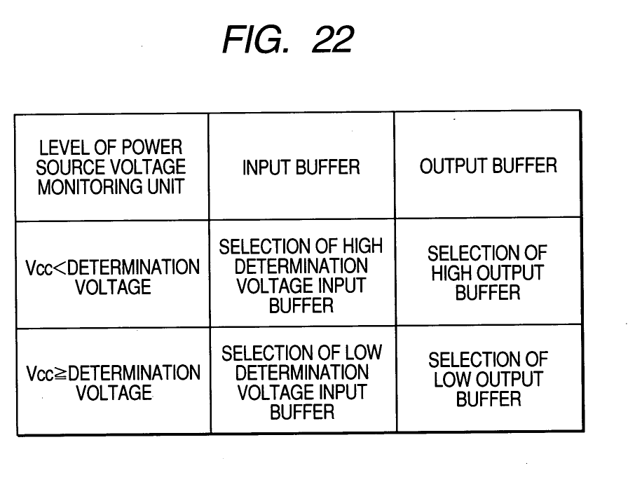

FIG. 20 is a block diagram of an information processing system according to a second embodiment of the invention. FIG. 21 is a flowchart showing operating process of a controller provided for the information processing system of FIG. 20. FIG. 22 is an explanatory diagram showing an example of I/O buffer selection by a power source voltage monitoring unit provided for the information processing system of FIG. 20.

In the second embodiment, the information processing system 1 (FIG. 1) is constructed by the host 2 and the semiconductor memory managing device 3. The semiconductor memory managing device 3 is constructed by the controller 4 and the semiconductor memory 5 as shown in FIG. 20.

The controller 4 is constructed by the I/O buffers 6 and 7, I/O buffer switching unit 8, data transfer control unit 9, selectors 10 and 11 (FIG. 1), and the like in a manner similar to the first embodiment. The controller 4 is newly provided with a power source voltage monitoring unit 4a.

The power source voltage monitoring unit 4a compares the voltage level of the power source voltage VCC with a criterion voltage and, on the basis of the comparison result, outputs a control signal to the I/O buffer switching unit 8 to control the I/O buffers 6, 7, 12, and 13.

The operation of the controller 4 in the second embodiment will be described by using the flowchart of FIG. 21.

First, when the power source is turned on (step S601), the power source voltage monitoring unit 4a checks the voltage level of the power source voltage VCC (step S602). Based on the result of the check, the power source voltage monitoring unit 4a outputs a control signal to the I/O buffer switching unit 8 to control settings of the I/O buffers 6, 7, 12, and 13 (step S603).

FIG. 22 is an explanatory diagram showing an example of I/O buffer selection by the power source voltage monitoring unit 4a.

When the power source voltage VCC is lower than the criterion voltage, the power source voltage monitoring unit 4a selects the high threshold voltage input buffers 6b₂ and 7b₂ (FIG. 1) and the high voltage output buffers 6a₂ and 7a₂ (FIG. 1).

In the case where the power source voltage VCC is equal to or higher than the criterion voltage, the power source voltage monitoring unit 4a selects the low threshold voltage input buffers 6b₁ and 7b₁ (FIG. 1) and the low voltage output buffers 6a₁ and 7a₁ (FIG. 1).

After the power source voltage monitoring unit 4a performs the control of setting the I/O buffers 6, 7, 12, and 13, in FIG. 21, the other resetting process is executed by the controller 4 (step S604). After that, the controller 4 notifies the host 2 of end of the resetting process (step S605).

Also after the end of the resetting process, the power source voltage monitoring unit 4a monitors the voltage level of the power source voltage VCC. In the case where the power source voltage VCC becomes lower than the criterion voltage (step S606) or higher than the criterion voltage (step S607), the process in step S604 is executed.

Therefore, according to the second embodiment, the characteristics of the I/O buffers 6, 7, 12 and 13 can be automatically switched according to the voltage level of the power source voltage VCC, and the influence of noise and the like can be reduced.

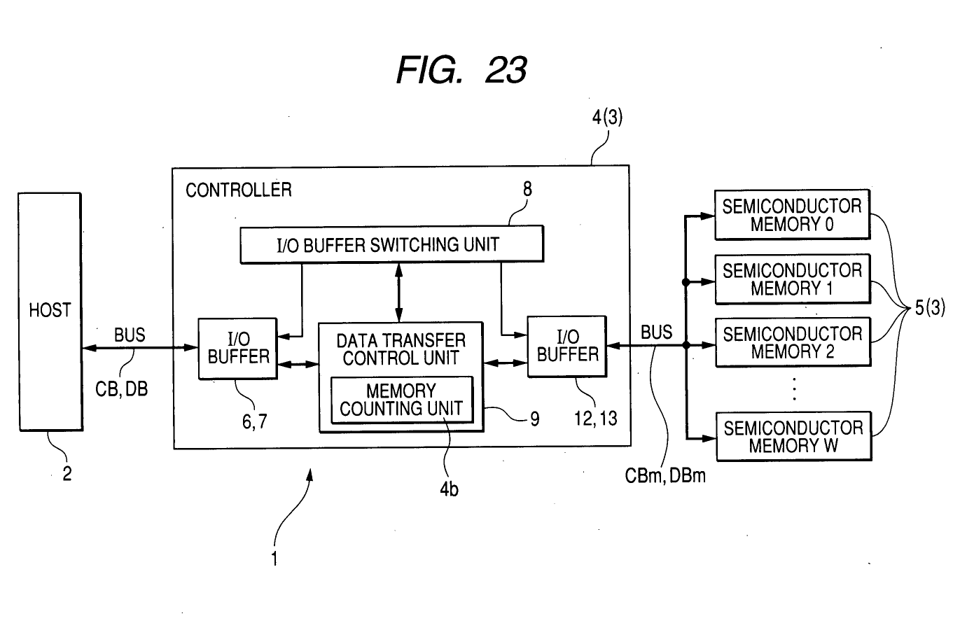

The characteristics of the I/O buffers 6, 7, 12, and 13 may not be switched according to the voltage level of the power source voltage VCC but may be determined by, for example, the number of the semiconductor memories 5 mounted on the semiconductor memory managing device 3 as shown in FIG. 23.

In this case, the data transfer control unit 9 has a memory counting unit 4b. The memory counting unit 4b counts the number of semiconductor memories 5 connected to the controller 4 and, on the basis of the result of counting, outputs a control signal to the I/O buffer switching unit 8.

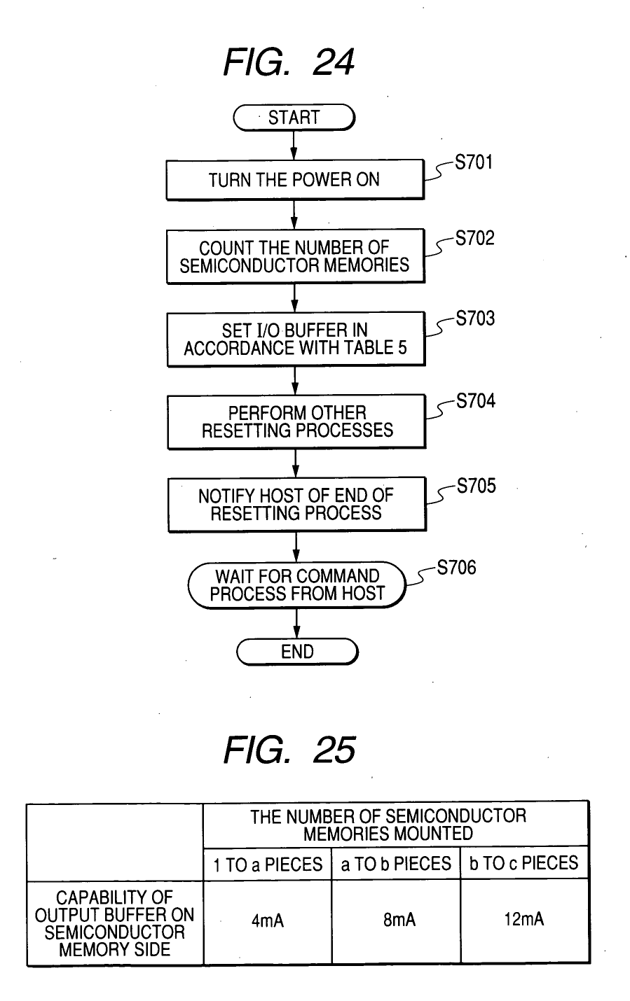

The operation of the controller 4 in which the data transfer control unit 9 has the memory counting unit 4b will be described by using the flowchart of FIG. 24.

First, when the power source is turned on (step S701), the memory counting unit 4b counts the number of semiconductor memories 5 connected (step S702) and, on the basis of the result of counting, outputs a control signal to the I/O buffer switching unit 8 (step S703).

FIG. 25 is an explanatory diagram showing an example of switching the output capability of the output buffers 6a and 7a by using the memory counting unit 4b. For example, the memory counting unit 4b performs a control so that the output capability of the output buffers 6a and 7a becomes about 4 mA in the case where the number of the semiconductor memories 5 is one to “a”, about 8 mA in the case where the number of the semiconductor memories 5 is larger than “a” and is equal to or smaller than “b”, and about 12 mA in the case where the number of the semiconductor memories 5 is larger than “b”.

Subsequently, in FIG. 24, the controller executes the other resetting process (step S704) and then notifies the host 2 of end of the resetting process (step S705).

In such a manner, the output capability of the output buffers 6a and 7a can be controlled to be optimum according to the number of the semiconductor memories 5 connected. Thus, noise immunity of the semiconductor memory managing device 3 can be improved.

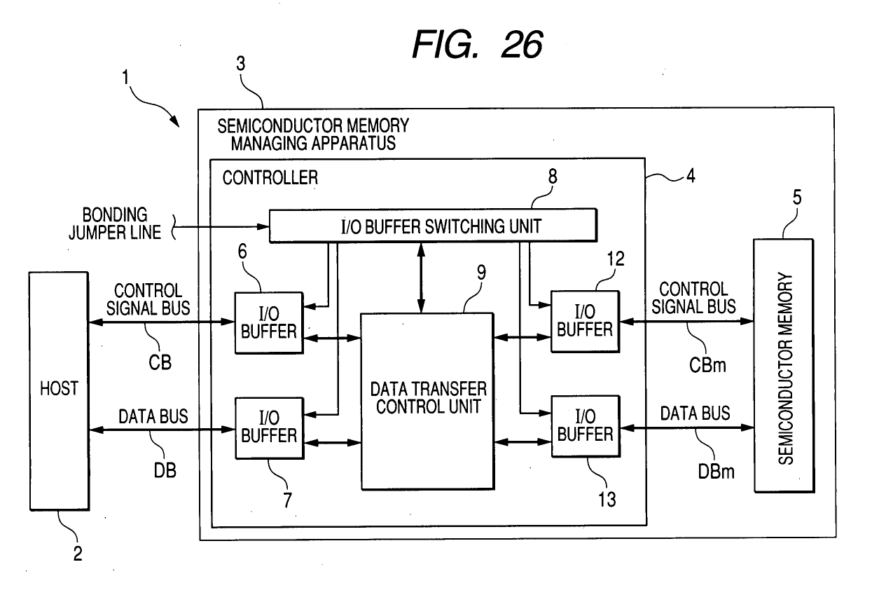

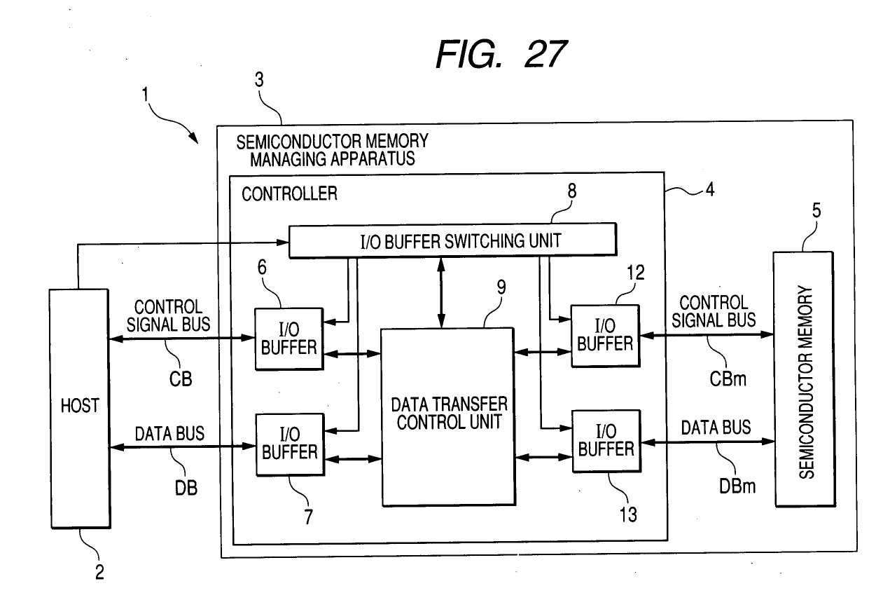

Alternately, the characteristics of the I/O buffers 6, 7, 12, and 13 may be switched in such a manner that, as shown in FIG. 26, a control signal is input via the external terminal of the controller 4 by a jumper switch, bonding option, or the like and, on the basis of the control signal, the I/O buffer switching unit 8 performs switching operation, or as shown in FIG. 27, a control signal is directly input from the host 2 via the external terminal of the controller 4 and the I/O buffer switching unit 8 performs switching on the basis of the control signal.

### Third Embodiment

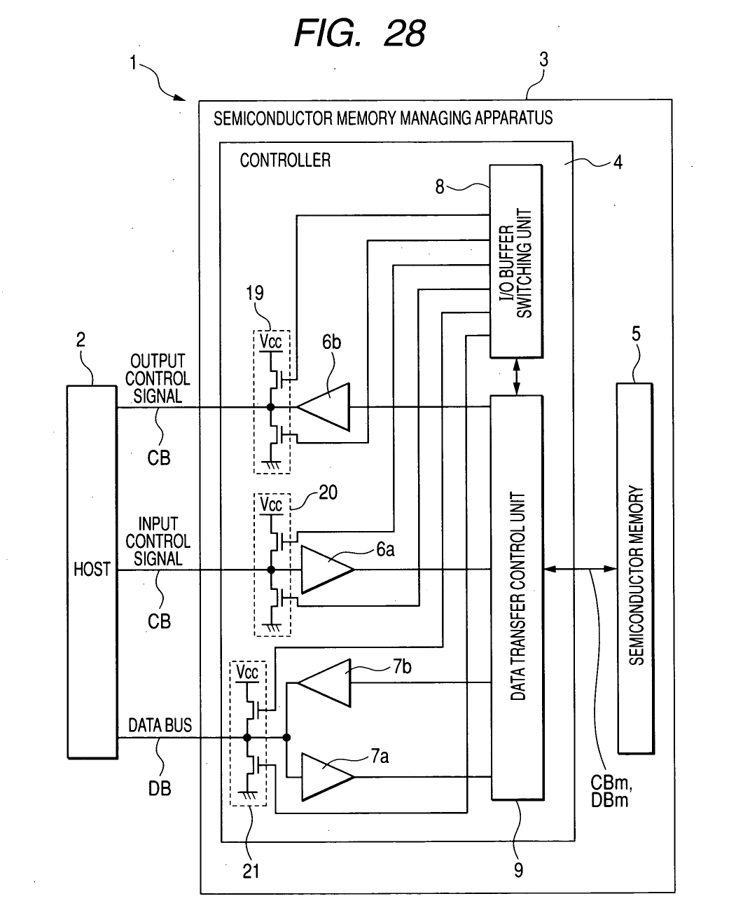

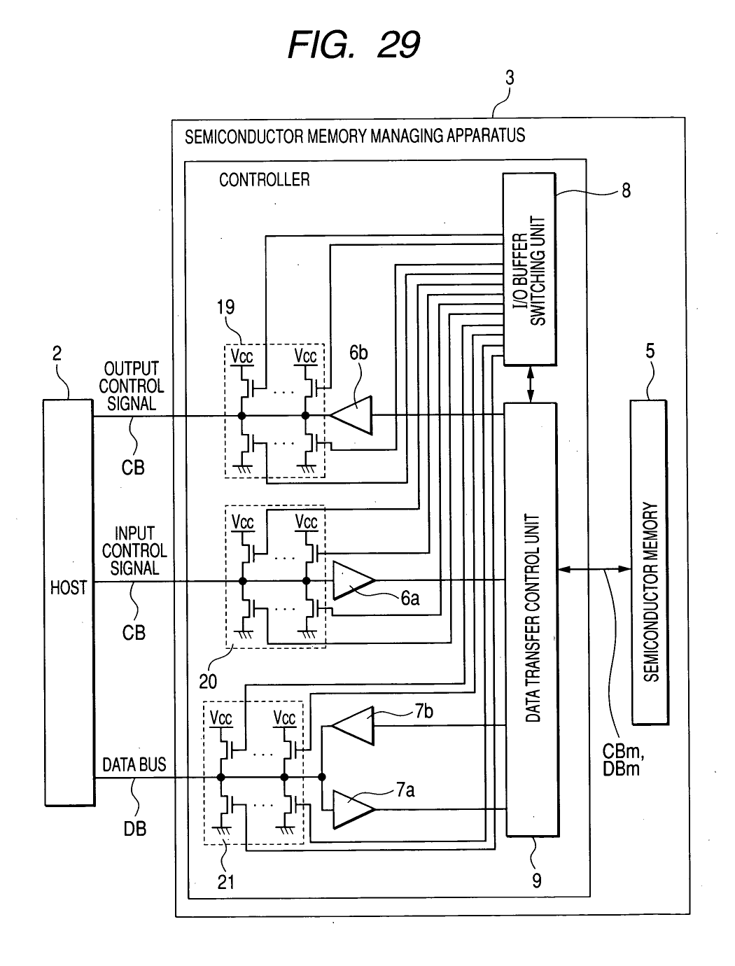

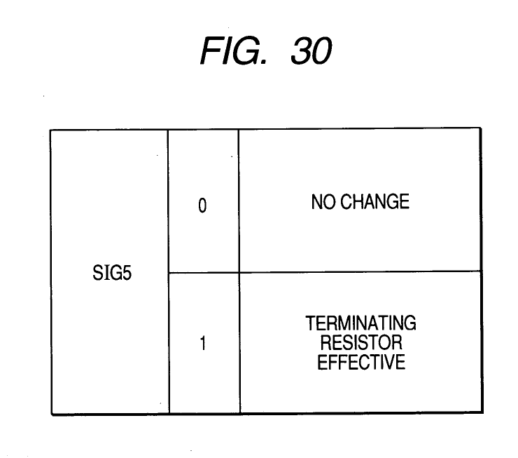

FIG. 28 is a block diagram showing an example of an information processing system according to a third embodiment of the invention. FIG. 29 is a block diagram showing another example of the information processing system of FIG. 28. FIG. 30 is an explanatory diagram showing an example of a conversion table of a terminating resistor in the information processing system of FIG. 28.

In the third embodiment, the information processing system 1 (FIG. 1) is constructed by the host 2 and the semiconductor memory managing device 3. The semiconductor memory managing device 3 is constructed by the controller 4 and the semiconductor memory 5 as shown in FIG. 28 and is newly provided with terminating resistors 19 to 21.

The terminating resistor 19 is connected to the output part of the output buffer 6a, the terminating resistor 20 is connected to the input part of the input buffer 6b, and the terminating resistor 21 is connected to the input and output parts of the output buffer 7a and the input buffer 7b.

Each of the terminating resistors 19 to 21 has a configuration that two (a pair of) MOS transistors are connected in series between the power source voltage VCC and the reference potential VSS, and the connection parts of the two transistors are connected to the output buffer 6a, input buffer 6b, output buffer 7a, and input buffer 7b. The gates of the transistors are connected to the I/O buffer switching unit 8.

Terminating resistors are also provided for the I/O buffers 12 and 13 (FIG. 2) provided between the semiconductor memory 5 and the data transfer control unit 9.

The I/O buffer switching unit 8 controls the terminating resistance value by changing the on-state resistances of the transistors by applying the voltage having the reference potential VSS level, power source voltage VCC level, or the intermediate level to the gates of the transistors constructing the terminating resistors 19 to 21.

Therefore, the terminating resistors 19 to 21 can be also said as MOS resistors whose resistance values can be dynamically varied. The terminating resistors 19 to 21 can separately control a MOS resistor connected to the reference potential VSS and a MOS resistor connected to the power source voltage VCC side and their resistance values can be varied. Consequently, the terminating resistors 19 to 21 may be used not as the terminating resistors but as pull-up resistors or pull-down resistors.

Each of the terminating resistors 19 to 21 may be constructed by, for example, four or more transistors as shown in FIG. 29. Although two (a pair of) MOS transistors are connected in series between the power source voltage VCC and the reference potential VSS in FIG. 28, four or more (two or more pairs of) transistors may be also connected in series between the power source voltage VCC and the reference potential VSS.

In this case, by changing the on-state resistance of the pair of transistors, a plurality of MOS resistors can be generated and it becomes unnecessary to apply an intermediate voltage to the gate terminal of each transistor.

Accordingly, an analog circuit and the like for generating the intermediate voltage become unnecessary and the controller 4 can be constructed only by digital circuits. Thus, the cost of the controller 4 can be reduced.

The terminating resistors 19 to 21 shown in FIGS. 28 and 29 can be applied to control methods of, for example, the control with the CRC data in FIG. 2, the control with ECC data in FIG. 5, control by noise detection in FIG. 9, the control with the command from the host 2 in FIG. 16, the control with the number of memories connected in FIG. 23, and the control via an external terminal shown in FIGS. 26 and 27.

FIG. 30 is a conversion table showing a setting example when the terminating resistors 19 to 21 are applied to the semiconductor memory managing device 3 having the noise detecting circuit 9g shown in FIG. 9.

When the noise detecting circuit 9g detects noise, that is, when the signal noise occurrence detection signal SIG5 becomes ‘1’, the terminating resistors 19 to 21 are made valid. In FIG. 30, only a valid or invalid state is set. For example, a circuit of monitoring a buffer signal and gradually changing the terminating resistance value from a high resistance value to a low resistance value to make adjustment, thereby obtaining an optimum terminating resistance value may be also used.

Thus, according to the third embodiment, noise can be efficiently reduced by varying the terminating resistance value in accordance with the state of a signal, and noise immunity of the semiconductor memory managing device 3 can be improved.

Although the invention achieved by the inventors herein has been concretely described above, obviously, the invention is not limited to the foregoing embodiments but can be variously changed without departing from the gist of the invention.

The I/O buffer control technique of the invention is suitable for a technique for improving noise immunity in a memory device.

1. A memory device comprising:
one or more semiconductor memories; and
an information processor,
wherein the information processor is capable of controlling, on the basis of operation programs, arbitrary one of reading data stored in the one or more semiconductor memories, performing a predetermined process, and writing data to one of the one or more semiconductor memories, and has a buffer switching control unit, and
wherein the buffer switching control unit performs a control of switching output voltage and drivability of an output buffer and a signal criterion level of an input buffer, and the output buffer and the input buffer are structured in the information processor.

2. The memory device according to claim 1, wherein the buffer switching control unit detects the presence or absence of an error in transfer data and, on the basis of a detection result, performs a control of switching the output buffer and the input buffer.

3. The memory device according to claim 1,
wherein the buffer switching control unit has a noise detector for detecting the presence or absence of noise in transfer data, and
wherein the buffer switching control unit performs a control of switching the output buffer and the input buffer on the basis of a result of detection of the noise detector.

4. The memory device according to claim 1, wherein the buffer switching control unit has a power source voltage monitoring unit for comparing a power source voltage supplied from the outside with a criterion voltage, and according to a result of comparison of the power source voltage monitoring unit, performs a control of switching the output buffer and the input buffer.

5. The memory device according to claim 3,
wherein each of the output buffer and the input buffer has a terminating resistor, and
wherein a resistance value of the terminating resistor varies on the basis of a control signal of the buffer switching control unit.

6. The memory device according to claim 1,
wherein the buffer switching control unit receives a control signal for switching the output voltage and drivability of the output buffer and a signal criterion level of the input buffer, and
wherein the control signal input to the buffer switching control unit is a signal that is input from the outside of the information processor.

7. The memory device according to claim 6, wherein the control signal input to the buffer switching control unit is a command that is output from outside of the memory device.

8. The memory device according to claim 7,
wherein each of the output buffer and the input buffer has a terminating resistor, and
wherein a resistance value of the terminating resistor varies on the basis of a control signal of the buffer switching control unit.

9. A memory device comprising:
one or more semiconductor memories; and
an information processor,
wherein the information processor is capable of controlling, on the basis of operation programs, arbitrary one of reading data stored in the one or more semiconductor memories, performing a predetermined process, and writing data to one of the one or more semiconductor memories, and has a buffer switching control unit,
wherein the buffer switching control unit performs a control of switching a signal criterion level of an input buffer being structured in the information processor in accordance with a state of an input/output signal, and performs a control of switching the output voltage and drivability of an output buffer being structured in the information processor on the basis of a control signal that is input from the outside.

10. The memory device according to claim 9, wherein the buffer switching control unit detects the presence or absence of an error in transfer data and, on the basis of a detection result, performs a control of switching the input buffer.

11. The memory device according to claim 9, wherein the buffer switching control unit detects the presence or absence of noise in transfer data and, on the basis of a detection result, performs a control of switching the input buffer.

12. The memory device according to claim 11,
wherein each of the output buffer and the input buffer has a terminating resistor, and
wherein a resistance value of the terminating resistor varies according to a control signal of the buffer switching control unit.

13. A memory device comprising:
one or more semiconductor memories; and
an information processor,
wherein the information processor is capable of controlling, on the basis of operation programs, arbitrary one of reading data stored in the one or more semiconductor memories, performing a predetermined process, and writing data to one of the one or more semiconductor memories, and has a buffer switching control unit,
wherein the buffer switching control unit performs a control of switching output voltage and drivability of an output buffer and a signal criterion level of an input buffer, and the output buffer and the input buffer are structured in the information processor, on the basis of buffer setting information, and
wherein the buffer setting information which is read by the buffer switching control unit is stored in one of the one or more semiconductor memories and is changeable.

14. A memory device comprising:
one or more semiconductor memories; and
an information processor,
wherein the information processor is capable of controlling, on the basis of operation programs, arbitrary one of reading data stored in the one or more semiconductor memories, performing a predetermined process, and writing data to one of the one or more semiconductor memories, and has a buffer switching control unit, and
wherein the buffer switching control unit counts the number of the semiconductor memories and, in accordance with the result of counting, performs a control of switching output voltage and drivability of an output buffer, which is structured in the information processor.

15. The memory device according to claim 14,
wherein each of the output buffer and the input buffer has a terminating resistor, and
wherein a resistance value of the terminating resistor varies on the basis of a control signal of the buffer switching control unit.
